(19) United States
(12) Patent Application Publication
(10) Pub. No.: US 2007/0082466 A1
(43) Pub. Date: Apr. 12, 2007

(54) High density plasma chemical vapor deposition apparatus, operating method thereof, and method of manufacturing semiconductor device

(75) Inventor: Cheon Man Shim, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/545,991

(22) Filed: Oct. 10, 2006

(30) Foreign Application Priority Data
Oct. 12, 2005 (KR) 10-2005-0096001

(51) Int. Cl. C23F 1/00; H01L 21/20; C23C 16/00; H01L 21/31

(52) U.S. Cl. 438/478; 118/723 I; 156/345.48; 438/758

(57) ABSTRACT

Disclosed are a chemical vapor deposition apparatus capable of improving gap-fill characteristics, an operating method thereof, and a method of manufacturing a semiconductor device. The chemical vapor deposition apparatus includes a first induction coil installed on an upper portion of a chamber to feed a first power having a first radio frequency (RF) into the chamber; an electrostatic chuck corresponding to the first induction coil so as to feed a second power having a second RF into the chamber, in which the substrate is laid on the electrostatic chuck; and a gas nozzle for feeding a reaction gas into the chamber. The second RF is in a range of from 0.1 to 100 KHz.

### BACKGROUND OF THE INVENTION

1. Field of the Invention

The present invention relates to a semiconductor device. More particularly, the present invention relates to a high density plasma chemical vapor deposition (HDP-CVD) apparatus capable of improving gap-fill characteristics, an operating method thereof, and a method of manufacturing a semiconductor device.

2. Description of the Related Art

With the development of semiconductor device manufacturing technologies, semiconductor devices are highly integrated, and multi-layered metal interconnection structures are provided in the semiconductor devices in order to improve the response speed of the semiconductor devices. An interlayer dielectric layer is formed in the multi-layered metal interconnection structure using chemical vapor deposition (CVD). According to the CVD technology, a chemical source in a gas phase is fed into a chamber and undergoes a chemical reaction to deposit a desired material onto a surface of the wafer, so that an interlayer dielectric layer and the like can be deposited on the surface of the wafer.

As the semiconductor devices have been highly integrated, demands for precise critical dimension control and higher aspect ratios for the trench isolation process or the interlayer dielectric layer increase. Thus, an interval between the metal interconnections has gradually decreased to a level of micro size. For this reason, it is difficult to completely fill a gap formed between metal interconnections using plasma CVD technology.

In this regard, a high density plasma CVD process has been developed so as to maximize the capability of filling a gap formed between metal interconnections.

In order to improve the ionization efficiency, the high density plasma CVD process is performed at a pressure of a few mtorrs, which is significantly lower than that of the conventional plasma CVD process, while applying a magnetic field to a plasma chamber together with an electric field. Accordingly, the high density plasma CVD process can obtain a great amount of accelerated energy as compared with that of the conventional plasma CVD process, and can generate a greater amount of reactive radicals due to the higher ionization density. That is, the high density plasma CVD process can simultaneously perform deposition and etch back by using inert gas, thereby effectively filling the gap having a higher aspect ratio.

A high density plasma CVD apparatus employing a high density plasma CVD technique uses a radio frequency power for generating plasma and a bias power for collecting activated species into the gap formed between the metal interconnections. In general, the bias power has a frequency band of a few MHz.

When filling a gap in a semiconductor device using conventional high density plasma CVD apparatus, that is, as shown in FIG. 1, when filling a trench having a predetermined depth in the semiconductor device 1 with an insulating layer 2, such as USG (undoped silicate glass) or oxide silicon, the electric field may be concentrated at an edge portion 3 of the semiconductor substrate 1, so that the edge portion of the semiconductor substrate 1 has a higher etch rate than the top surface or a wall surface of the semiconductor substrate 1 (e.g., the planar upper surface of the substrate 1 or the sidewalls of the trench or via therein). In addition, particles of the etched insulating layer 2 are again deposited on the surface of the semiconductor substrate 1. Since the bias power has a frequency band of a few MHz, the particles deposited onto the surface of the semiconductor substrate 1 may collide with other particles being deposited onto the surface of the semiconductor substrate 1, thereby losing kinetic energy thereof. Thus, the particles cannot sufficiently move, so the particles are collected in one spot, form a protrusion.

Therefore, when filling the gap of the semiconductor device using conventional high density plasma CVD apparatus, since the bias power has the frequency band of a few MHz (that is, 10-6 second unit), the activated particles decomposed from the insulating layer 2 by the plasma may reach the surface of a wafer before the particles move to a stable position on the water. Thus, the particles may collide with other particles, so that the particles tend to be fixed in one spot of the wafer without moving toward a stable position. Accordingly, a relatively large amount of particles may be stacked on an edge portion of a shallow trench isolation layer or on the top surface of the metal interconnection. Such particles may cause voids 4, thereby degrading the gap-fill capability.

### SUMMARY OF THE INVENTION

Accordingly, the present invention is directed to a high density plasma CVD apparatus that substantially obviates one or more of the problems due to limitations and disadvantages of the related art.

An object of the present invention is to provide a high density plasma chemical vapor deposition apparatus capable of improving gap-fill characteristics, an operating method thereof, and a method of manufacturing a semiconductor device.

Additional advantages, objects, and features of the invention will be set forth in part in the description which follows and in part will become apparent to those skilled in the art upon examination of the following or may be learned from practice of the invention. The objectives and other advantages of the invention may be realized and attained by the structure(s) particularly pointed out in the written description and claims hereof as well as the appended drawings.

According to a first embodiment of the present invention, there is provided a chemical vapor deposition (CVD) apparatus (e.g., for depositing materials on a substrate), the CVD apparatus comprising: a first induction coil on an upper portion of a chamber configured to feed a first power having a first radio frequency (RF) into the chamber; an electrostatic chuck corresponding to the first induction coil configured to feed a second power having a second RF in a range of from 0.1 to 100 KHz into the chamber and hold a substrate thereon; and a gas nozzle for feeding a reaction gas into the chamber.

According to a second embodiment of the present invention, there is provided a chemical vapor deposition (CVD) apparatus (e.g., for depositing materials on a substrate), the CVD apparatus comprising: a first induction coil in a chamber configured to feed a first power having a first radio frequency (RF) into the chamber; an electrostatic chuck corresponding to the first induction coil configured to hold a substrate thereon and feed a second power including an analog AC power and having a second RF in a range of 0.1 to 100 KHz into the chamber; and a gas nozzle for feeding reaction gas into the chamber.

According to a third embodiment of the present invention, there is provided a chemical vapor deposition (CVD) apparatus (e.g., for depositing materials on a substrate), the CVD apparatus comprising: a first induction coil in a chamber to feed a first power having a first radio frequency (RF) into the chamber; an electrostatic chuck corresponding to the first induction coil configured to hold a substrate and feed a second power including a digital pulse power and having a second RF in a range of from 0.1 to 100 KHz into the chamber; and a gas nozzle for feeding reaction gas into the chamber.

According to a fourth embodiment of the present invention, there is provided a method of operating a chemical vapor deposition (CVD) apparatus (e.g., for depositing materials on a substrate), the method comprising the steps of: feeding a first power having a first radio frequency (RF) into a chamber using a first induction coil on an upper portion of the chamber; feeding a second power having a second RF in a range of from 0.1 to 100 KHz into the chamber using an electrostatic chuck corresponding to the first induction coil and on which the substrate is laid; and feeding a reaction gas into the chamber.

According to a fifth embodiment of the present invention, there is provided a semiconductor device comprising: a substrate including a trench; and an insulating layer formed on the substrate using a chemical vapor deposition apparatus which feeds a radio frequency having a range of from 0.1 to 100 KHz using an electrostatic chuck on which the substrate is laid.

It is to be understood that both the foregoing general description and the following detailed description of the present invention are exemplary and explanatory, and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention together with the description, and serve to explain the principle of the invention.

FIG. 1 is a view illustrating a plasma oxide layer formed by a conventional high-density plasma CVD apparatus;

FIG. 2 is a cross-sectional view illustrating the structure of a high-density plasma CVD apparatus according to the exemplary embodiment of the present invention; and

FIG. 3 is a view illustrating a plasma insulating layer formed by a high-density plasma CVD apparatus according to the exemplary embodiment of the present invention.

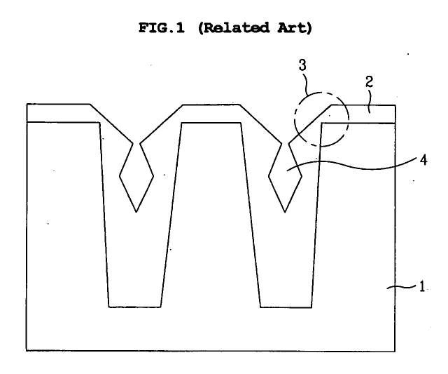

### DETAILED DESCRIPTION OF THE PREFERRED EMBODIMENTS

Hereinafter, preferred embodiments of the present invention will be described with reference to the accompanying drawings.

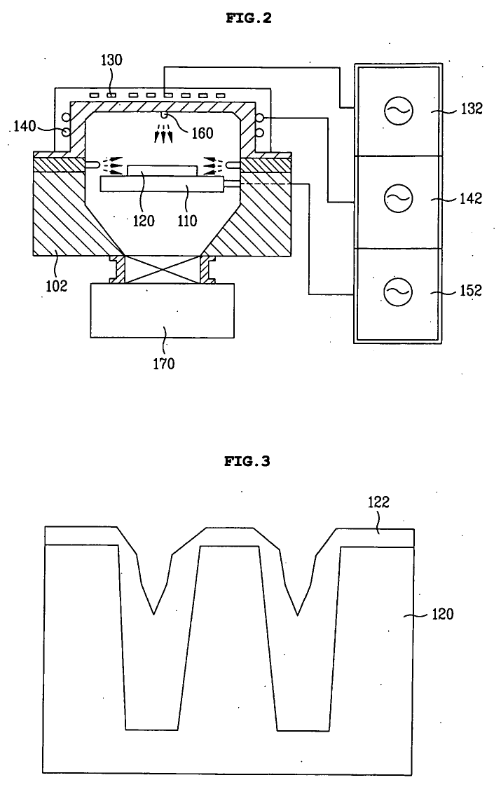

FIG. 2 is a schematic view illustrating the structure of a high-density plasma CVD apparatus according to the exemplary embodiment of the present invention.

Referring to FIG. 2, the high-density plasma CVD apparatus includes an electrostatic chuck 110 installed below a chamber to pick up, hold and/or secure a semiconductor substrate 120, an upper induction coil 130 installed at an upper portion of the chamber 102, a side induction coil 140 installed at a side of the chamber 102, a plurality of gas nozzles 160 extending into the chamber 102 in order to inject a reaction gas into the chamber 102, a first RF generator 132 for feeding a first power having a first RF to the upper induction coil 130, a second RF generator 142 for feeding a second power having a second RF to the side induction coil 140, a third RF generator 152 for feeding a third power having a third RF to the electrostatic chuck 110, and a pump 170 installed below the electrostatic chuck 110 so as to apply a vacuum to the chamber 102 or release the vacuum from the chamber 102.

The upper induction coil 130 feeds the first power having the first RF, which is generated from the first RF generator 132, into the chamber 102. Accordingly, the reaction gas injected into the chamber 102 is ionized by means of the first power having the first RF, so that a plasma is generated. The first RF is generally about 2 Mhz and the first power is in a range of from 1000 to 5000 W.

If plasma is sufficiently generated by means of the upper induction coil 130, the side induction coil 140 and the second RF generator 142 are not needed. That is, the side induction coil 140 is optionally provided in order to generate high density plasma in the chamber 102.

The side induction coil 140 feeds the second power having the second RF, which is generated from the second RF generator 142, into the chamber 102. Thus, high density plasma can be generated in the chamber 102 by means of the first power having the first RF provided from the upper induction coil 130 and the second power having the second RF provided from the side induction coil 140. The second RF is also about 2 Mhz and the second power is also in a range of from 1000 to 5000 W. Alternatively, the second RF is identical to or different from the first RF.

The electrostatic chuck 110 feeds the third power having the third RF, which is generated from the third RF generator 152, into the chamber 102. The activated species are attracted to the electrostatic chuck 110 due to the power applied to the electrostatic chuck 110, the field generated from application of power applied to the electrostatic chuck 110, and/or a plasma generated by the third power having the third RF.

The third RF is in a range of from 0.1 to 100 KHz, and the third power is in a range of from 500 to 4000 W.

According to the exemplary embodiments of the present invention, the third power of from 500 to 4000 W having the third RF of from 0.1 to 100 KHz is fed from the electrostatic chuck 110. Accordingly, the frequency level of the power from the electrostatic chuck is lowered from the MHz level to the KHz level, so it takes a relatively long time for the activated species to collide with other particles. Thus, the activated species are relatively distributed without collecting in one or more certain spots, so that protrusions that may cause voids generally do not form.

The third power includes an analog AC power (or power component), having a sine wave.

Alternatively, the third power includes a digital pulse power, having a square wave. To this end, the third RF generator 152 can generate the digital pulse power having the square wave. In this case, the on-duty period of such a square power wave is in a range of from 0.01 to 0.99 or any range of values therein (e.g., from 0.05 to 0.75, 0.1 to 0.5, etc.). At this time, the third RF may be in a range of from 0.1 to 100 KHz, or the third RF may have a frequency band in the MHz range, similar to that of the related art. The third power advantageously has a digital pulse waveform. When the third power has the digital pulse waveform, the power is applied only during the on-duty period, so that the activated species rarely collide (or collide less frequently) with other particles, thereby preventing or reducing the incidence of voids.

The gas nozzles 160 receive source gases for the material to be deposited, such as silane (SiH₄), oxygen (O₂) and an inert gas, such as argon (Ar), from a tank (not shown) when the material is a silicon oxide. Alternatively, the source gases for the material to be deposited may include tungsten hexafluoride (WF₆), hydrogen (H₂), and optionally an inert gas, such as argon (Ar), from a tank (not shown) when the material is tungsten.

As shown in FIG. 3, the inert gas forms a high density plasma insulating layer 122 in the trench in the semiconductor substrate 120. The high density plasma insulating layer 122 may include silicon oxide (SiO₂) or USG (undoped silicate glass).

Hereinafter, the operation of the high density plasma CVD apparatus having the above structure will be described.

First, the semiconductor substrate 120 having trenches therein is loaded into the chamber 102, and then the semiconductor substrate 120 is laid or placed on the electrostatic chuck 110. Although it is not illustrated, the electrostatic chuck 110 can have a coolant path therein through which coolant is circulated in order to maintain the semiconductor substrate 120 at a constant temperature, thereby preventing the semiconductor substrate 120 from being damaged by a high temperature during the semiconductor manufacturing process.

Reaction gases are fed into the chamber 102 through the gas nozzles 160. The reaction gases may include silane (SiH₄), oxygen (O₂) and an inert gas, such as argon (Ar) when the material being deposited into the trench comprises a silicon oxide (e.g., SiO₂ or USG).

Then, the first power having the first RF is fed from the upper induction coil 130 to generate a plasma. The first RF may be about 2 Mhz, and the first power is in a range of from 1000 to 5000 W.

The second power having the second RF can be fed from the side induction coil 140. In this case, a higher density plasma can be generated in the chamber 102 by the second power having the second RF. The second RF may also be about 2 Mhz, and the second power is in a range of from 1000 to 5000 W. However, the second RF may be identical to or different from the first RF.

Then, the third power having the third RF is fed from the electrostatic chuck 110. The activated species generated in the chamber 102 are attracted to the electrostatic chuck 110 by the third power having the third RF. Thus, the activated species may be deposited on the semiconductor substrate 120 on the electrostatic chuck 110, to form a high density plasma insulating layer 122 on the semiconductor substrate 120.

The third RF is in a range of from 0.1 to 100 KHz, and the third power is in a range of from 500 to 4000 W. The third power may include an analog AC power, which may be characterized as a sine wave. Alternatively, the third power may include a digital pulse power having a square wave.

When the high density plasma insulating layer 122 is formed on the entire surface of the semiconductor substrate 120, as shown in FIG. 3, silicon oxide particles or USG particles, which may be created during the plasma etching process, are attracted to the surface of the semiconductor substrate 120 and may move toward the trench. thereby the trench can be filled with the plasma insulating layer 122 without creating or with a reduced number of voids. That is, since the third power may comprise (i) an analog AC power having a low frequency or (ii) a digital pulse power, it may take a relatively long time for the activated species to collide with other particles, so that the activated species can make long-distance movements without necessarily colliding with other particles. Thus, the high density plasma insulating layer 122 can fill the trench of the semiconductor substrate 120 in a uniform thickness without generating a significant number of voids.

According to the present invention, the electrostatic chuck feeds a power having a low-frequency or digital pulse waveform, so that voids can be reduced or prevented when filling a gap such as a trench with a plasma insulating layer. Thus, the gap-fill characteristics of the insulating layer can be improved, so that a trench having a higher aspect ratio can be obtained, and metal or silicon can be prevented from being damaged by the plasma.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A chemical vapor deposition (CVD) apparatus, comprising:
a first induction coil on an upper portion of a chamber configured to feed a first power having a first radio frequency (RF) into the chamber;
an electrostatic chuck corresponding to the first induction coil configured to feed a second power having a second RF in a range of from 0.1 to 100 KHz into the chamber and hold a substrate thereon; and
a gas nozzle for feeding a reaction gas into the chamber.

2. The VD apparatus as claimed in claim 1, wherein the first RF is in a range of from 1 to 3 Mhz, and the first power is in a range of from 1000 to 5000 W.

3. The CVD apparatus as claimed in claim 1, wherein the second power is in a range of from 500 to 4000 W.

4. The CVD apparatus as claimed in claim 1, wherein the second power includes an analog AC power.

5. The CVD apparatus as claimed in claim 1, wherein the second power includes a digital pulse power.

6. The CVD apparatus as claimed in claim 5, wherein an on-duty period of the digital pulse power is in a range of from 0.01 to 0.99.

7. The CVD apparatus as claimed in claim 1, further comprising a second induction coil at a lateral side of the chamber configured to feed a third power having a third RF into the chamber.

8. The CVD apparatus as claimed in claim 7, wherein the third RF is in a range of from 1 to 3 Mhz, and the third power is in a range of from 1000 to 5000 W.

9. The CVD apparatus as claimed in claim 7, wherein the third RF is identical to the first RF.

10. The CVD apparatus as claimed in claim 7, wherein the third RF is different from the first RF.

11. A chemical vapor deposition (CVD) apparatus, the CVD apparatus comprising:
a first induction coil in a chamber configured to feed a first power having a first radio frequency (RF) into the chamber;
an electrostatic chuck corresponding to the first induction coil configured to hold a substrate thereon and feed a second power including an analog AC power and having a second RF in a range of from 0.1 to 100 KHz into the chamber; and
a gas nozzle for feeding a reaction gas into the chamber.

12. The CVD apparatus as claimed in claim 11, further comprising a second induction coil at a lateral side of the chamber to feed a third power having a third RF into the chamber.

13. A chemical vapor deposition (CVD) apparatus, comprising:
a first induction coil in a chamber to feed a first power having a first radio frequency (RF) into the chamber;
an electrostatic chuck corresponding to the first induction coil configured to hold a substrate thereon and feed a second power having a second RF in a range of from 0.1 to 100 KHz into the chamber, the second power including a digital pulse power; and
a gas nozzle for feeding a reaction gas into the chamber.

14. The CVD apparatus as claimed in claim 13, wherein an on-duty period of the digital pulse power is in a range of from 0.01 to 0.99.

15. The CVD apparatus as claimed in claim 13, further comprising a second induction coil at a lateral side of the chamber to feed a third power having a third RF into the chamber.

16. A method of operating a chemical vapor deposition (CVD) apparatus, the method comprising the steps of:
feeding a first power having a first radio frequency (RF) into a chamber using a first induction coil on an upper portion of the chamber;
feeding a second power having a second RF in a range of from 0.1 to 100 KHz into the chamber using an electrostatic chuck installed on which the substrate is laid; and
feeding a reaction gas into the chamber.

17. The method as claimed in claim 16, wherein the second power includes an analog AC power.

18. The method as claimed in claim 16, wherein the second power includes a digital pulse power.

19. The method as claimed in claim 18, wherein an on-duty period of the digital pulse power is in a range of 0.01 to 0.99.

20. A semiconductor device comprising:
a substrate including a trench; and
an insulating layer formed on the substrate using a chemical vapor deposition apparatus which feeds a radio frequency having a range of 0.1 to 100 KHz using an electrostatic chuck on which the substrate is laid.
